(19) United States
(12) Patent Application Publication
(10) Pub. No.: US 2011/0266574 A1
(43) Pub. Date: Nov. 3, 2011

(54) LED PACKAGE

(75) Inventors: CHI-WEI LIAO, Hsinchu (TW); WEN-LIANG TSENG, Hsinchu (TW); CHIH-YUNG LIN, Hsinchu (TW); MIN-TSUN HSIEH, Hsinchu (TW); CHING-LIEN YEH, Hsinchu (TW)

(73) Assignee: ADVANCED OPTOELECTRONIC TECHNOLOGY, INC., Hsinchu Hsien (TW)

(21) Appl. No.: 13/007,677

(22) Filed: Jan. 17, 2011

(30) Foreign Application Priority Data
Apr. 29, 2010 (CN) 201010159829.8

(51) Int. Cl. H01L 33/54

(52) U.S. Cl. 257/98; 257/E33.059; 257/E33.074

(57) ABSTRACT

An LED package includes a substrate, an LED die, and an encapsulating layer. The LED die is arranged on the substrate. The encapsulating layer covers the LED die and at least a part of the substrate. The encapsulating layer includes a light dispersing element. A light scattering intensity of the light dispersing element is proportional to the light intensity of light generated by the LED die and illuminated at the encapsulating layer. A luminance at a center of the LED package is substantially identical to that at a circumference of the LED package.

### BACKGROUND

1. Technical Field

The present disclosure generally relates to LED technology, and particularly to an LED package.

2. Description of the Related Art

Light emitting diodes (LEDs) have been promoted as a widely used light source by many advantages, such as high luminosity, low operational voltages, low power consumption, compatibility with integrated circuits, easy driving, long-term reliability, and environmental friendliness. LEDs are commonly applied in a plurality of lighting applications.

However, LED packages must overcome certain light illumination uniformity challenges. LED is a point light source and the center of the commonly used LED package has higher light intensity than the circumference. The non-uniformity of light illumination of the LED package will cause bad effects on the usage of LED.

What is needed, therefore, is an LED package, which can increase light illumination uniformity, and ameliorate the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the LED package. Moreover, in the drawings, like reference numerals designate corresponding parts throughout the views.

FIG. 1 is a schematic cross section of an LED package in accordance with a first embodiment.

FIG. 2 is a schematic plot of distribution curve of luminous intensity of the LED package of FIG. 1.

FIG. 3 is a view similar to FIG. 1 showing the LED package of FIG. 1 having a modified substrate.

FIG. 4 is a schematic cross section of an LED package in accordance with a second embodiment.

FIG. 5 is a schematic cross section of an LED package in accordance with a third embodiment.

FIG. 6 is a schematic top view of the atomization level of the outer surface of the LED package of FIG. 5.

FIG. 7 is a schematic cross section of an LED package in accordance with a fourth embodiment.

FIG. 8 is a schematic cross section of an LED package in accordance with a fifth embodiment.

FIG. 9 is a schematic cross section of an LED package in accordance with a sixth embodiment.

FIG. 10 is a schematic cross section of an LED package in accordance with a seventh embodiment.

FIG. 11 is a schematic cross section of an LED package in accordance with an eighth embodiment.

### DETAILED DESCRIPTION

Embodiments of an LED package as disclosed are described in detail here with reference to the drawings.

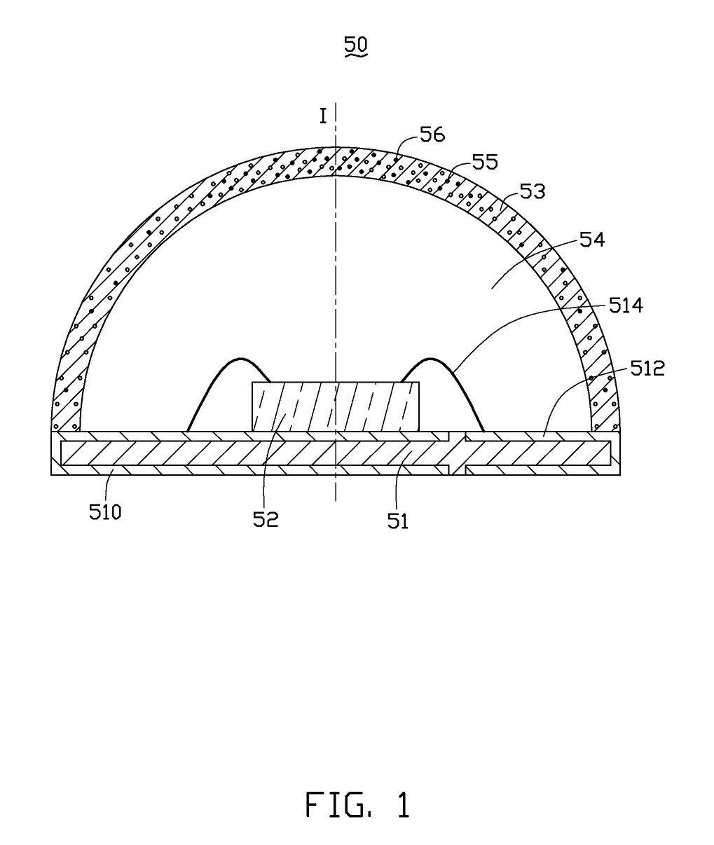

Referring to FIG. 1, an LED package 50 in accordance with a first embodiment includes a substrate 51, an LED die 52 arranged on the substrate 51, an encapsulating layer 53 covering the LED die 52, and a light dispersing element inside the encapsulating layer 53. The encapsulating layer 53 includes a luminescent material 55. The density of the light dispersing element is proportional to the intensity of light illuminated on the encapsulating layer 53.

The substrate 51 is Al₂O₃, silicon, SiC, ceramic, polymer, or insulant quartz. The substrate 51 includes a circuit electrically connecting with the LED die 52. The circuit includes a first electrode 510 and a second electrode 512. The LED die 52 is arranged on the first electrode 510 and electrically connecting with the first electrode 510 and the second electrode 512 through wires 514. The LED die 52 can also be arranged by manner of flip-chip (not shown). The first electrode 510 and the second electrode 512 of the circuit extend from the upper surface to the bottom surface of the substrate 51 to make the LED package 50 a surface mounted device (SMD).

The LED die 52 can be a compound semiconductor of group III-V elements or group II-VI elements. Light emitted from the LED die 24 can be visible, invisible, or a mixture of visible and invisible.

The encapsulating layer 53 is a transparent hemispherical shell with uniform thickness covering the LED die 52. Understandably, a number of the LED die 52 can be more than one and the encapsulating layer 53 can cover a plurality of LED dies. The encapsulating layer 53 defines a space 54 with the substrate 51, and the LED die 52 is arranged inside the space 54. The encapsulating layer 53 can be transparent material, such as silicone, epoxy, quartz, or glass.

The light dispersing element is a plurality of light scattering particles 56 spreading in the encapsulating layer 53. The density of the light scattering particles 56 is proportional to the intensity of light illuminated on the encapsulating layer 53 from the LED die 52. In this embodiment, the intensity of light illuminated on the encapsulating layer 53 from the LED die 52 is higher at the top (center) and lower at the bottom (periphery) of the encapsulating layer 53. So that the density of the light scattering particles 56 is higher at the top (center) and lower at the bottom (periphery) of the encapsulating layer 53. The light scattering particles 56 can be TiO₂, plastic, polymethylmethacrylate (PMMA), fused silica, Al₂O₃, MgO, or other transparent oxide. The shape of the light scattering particles 56 are not limited and can be spherical, rod, or any other shape. In this embodiment, the light scattering particles 56 are spherical.

The density of the luminescent material 55 is proportional to the intensity of light illuminated on the encapsulating layer 53 from the LED die 52. In this embodiment, the density of the luminescent material 55 is higher at the top (center) of the encapsulating layer 53 and lower at the bottom (periphery) of the encapsulating layer 53. Other optical element can also be filled between the LED die 52 and the encapsulating layer 53. The luminescent material 55 can be garnet compound, silicate, sulfide, phosphate, nitride, oxynitride, or SiAlON.

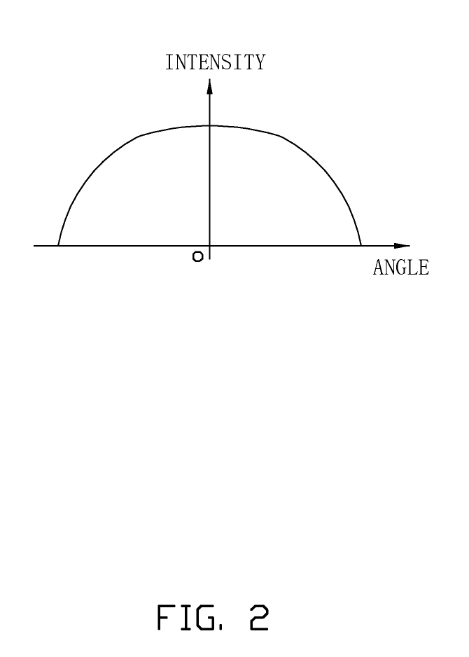

The LED package 50 includes an optical axis I. FIG. 2 is a schematic plot of distribution curve of luminous intensity of the LED package of FIG. 1. Referring to FIG. 2, the x-axis is the angle away from the optical axis I, and the y-axis is the intensity of light illuminated. The light intensity is basically the same near the optical axis I which means that the light illuminated by the LED package 50 has a higher uniformity.

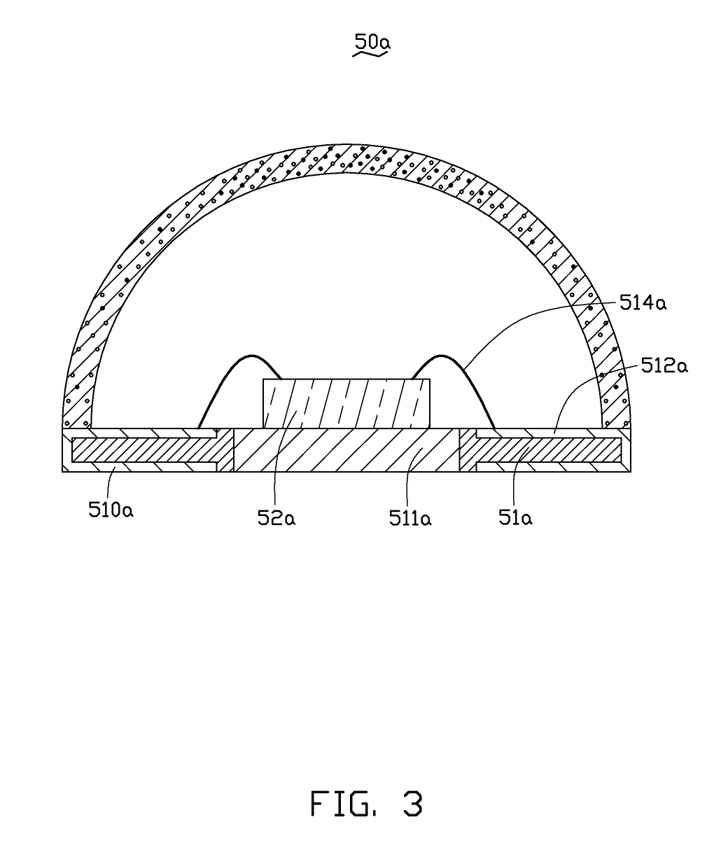

The substrate 51 of the LED package 50 in accordance with the first embodiment can be of other structure as shown in FIG. 3. The substrate 51a includes a circuit electrically connecting to an LED die 52a. The circuit includes a first electrode 510a and a second electrode 512a. A heat dissipating lump 511a is arranged in the middle of the substrate 51a. The LED die 52a is arranged on the heat dissipating lump 511a and electrically connects with the first electrode 510a and the second electrode 512a through wires 514a. The first electrode 510a and the second electrode 512a of the circuit extend from the upper surface to the bottom surface of the substrate 51a to make the LED package 50a a surface mounted device (SMD).

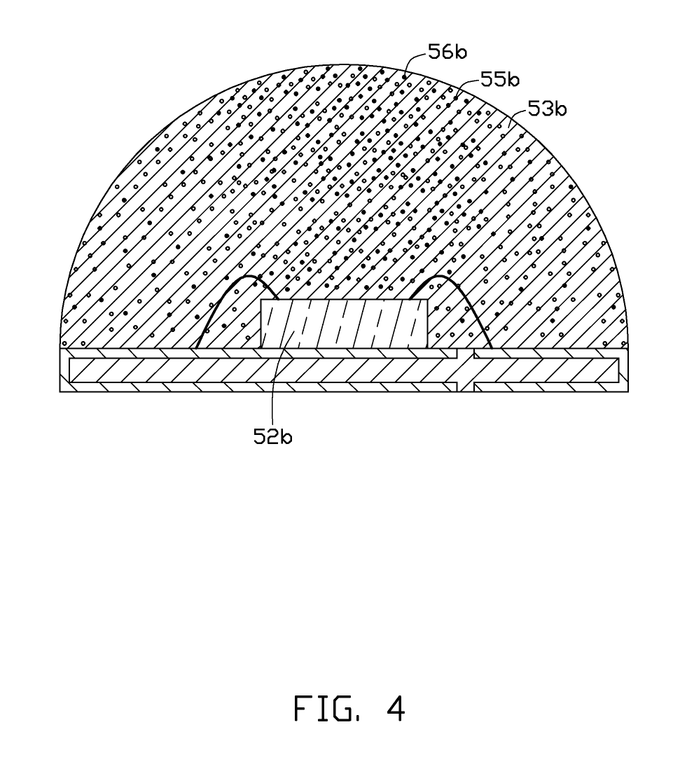

Referring to FIG. 4, an LED package in accordance with a second embodiment includes an encapsulating layer 53b directly covering the LED die 52b by molding. The luminescent material 55b and the light scattering particles 56b are arranged inside the encapsulating layer 53b.

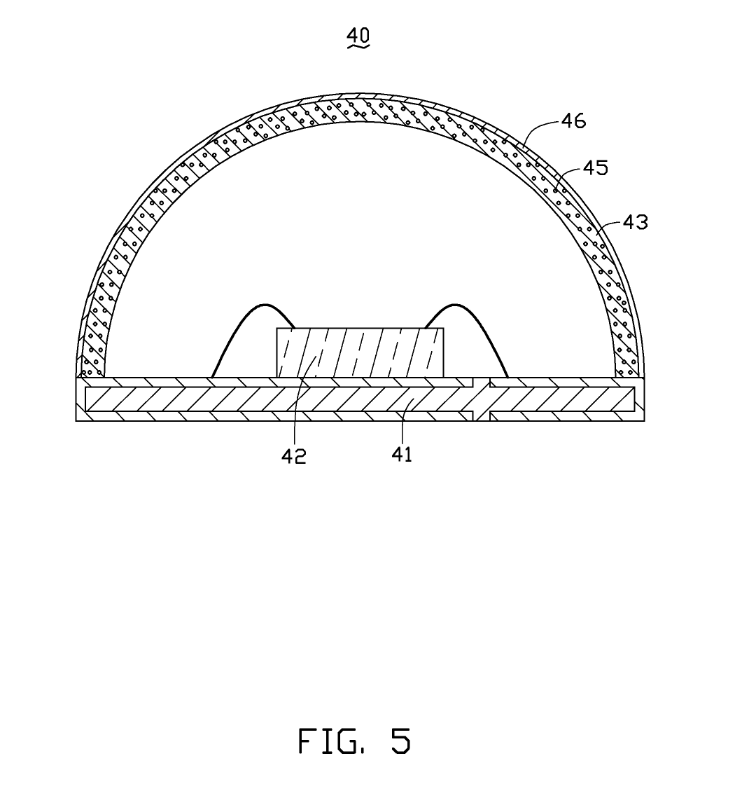

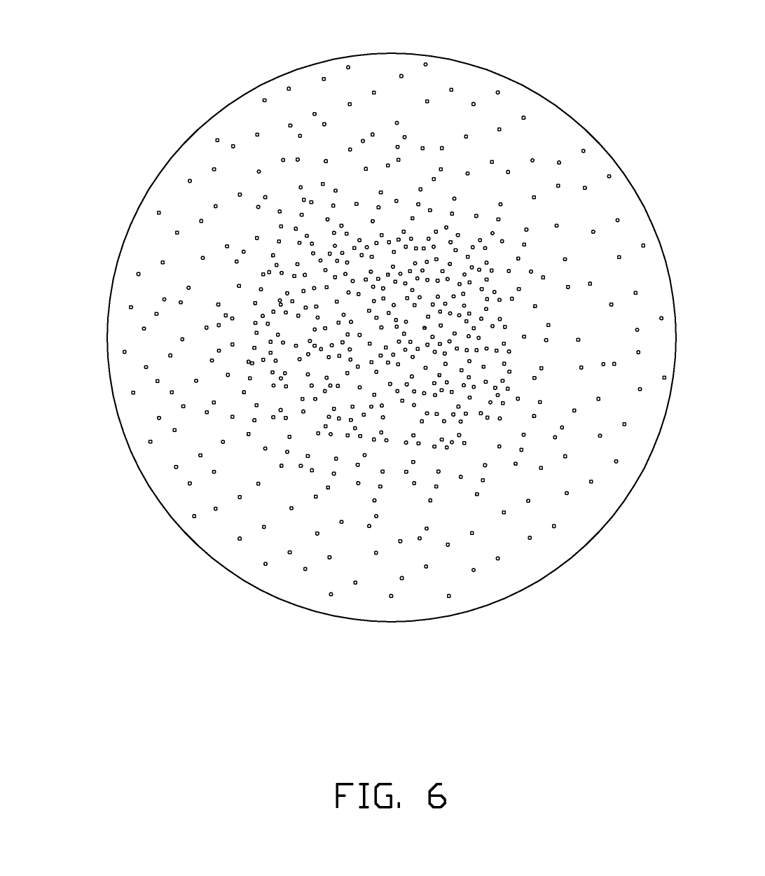

Referring to FIG. 5, an LED package 40 in accordance with a third embodiment includes a substrate 41, an LED die 42 arranged on the substrate 41, an encapsulating layer 43 covering the LED die 42, and a luminescent material 45 inside the encapsulating layer 43. The difference from the first embodiment is that there is no light scattering particles in the encapsulating layer 43 and the outer surface of the encapsulating layer 43 includes an atomization layer 46 as light dispersing element by atomization treatment. The degree of atomization is proportional to the light intensity illuminated on the encapsulating layer 43 from the LED die 42. In this embodiment, the degree of atomization is higher at the center and lower at the periphery. (as shown in FIG. 6)

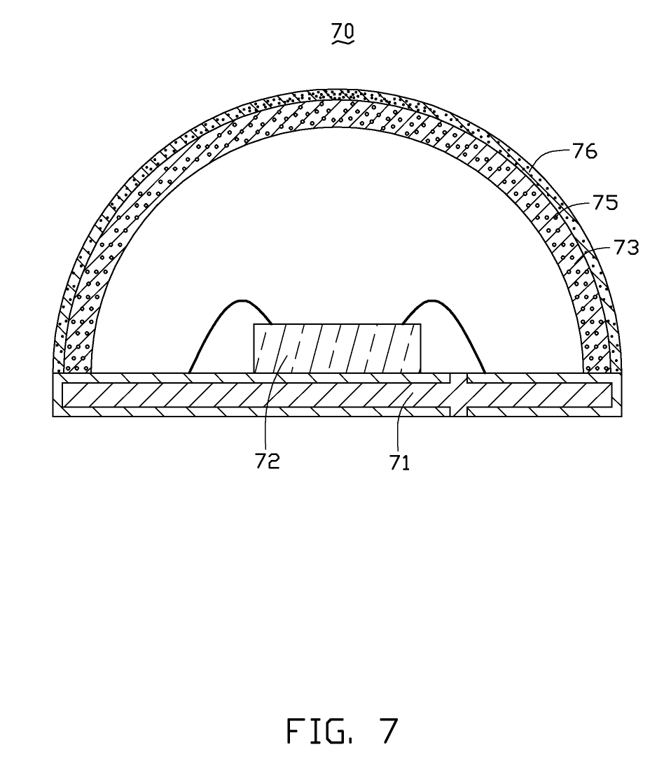

Referring to FIG. 7, an LED package 70 in accordance with a fourth embodiment includes a substrate 71, an LED die 72 arranged on the substrate 71, an encapsulating layer 73 covering the LED die 72, and a luminescent material 75 inside the encapsulating layer 73. The difference from the first embodiment is that there is no light scattering particles in the encapsulating layer 73 and the outer surface of the encapsulating layer 73 includes a sandblasted layer 76 as light dispersing element by sandblasting. The sand blasting layer 76 is formed by high speed impact of copper ore sand, quartz sand, emery sand, iron sand, or sea sand to the outer surface of the encapsulating layer 73. The sand blasting layer 76 includes a plurality of micro-recesses (not labeled) therein. The density of the micro-recesses of the sandblasted layer 76 is proportional to the light intensity illuminated on the encapsulating layer 73 from the LED die 72. In this embodiment, the density of micro-recesses of the sandblasted layer 76 is higher at the center and lower at the periphery.

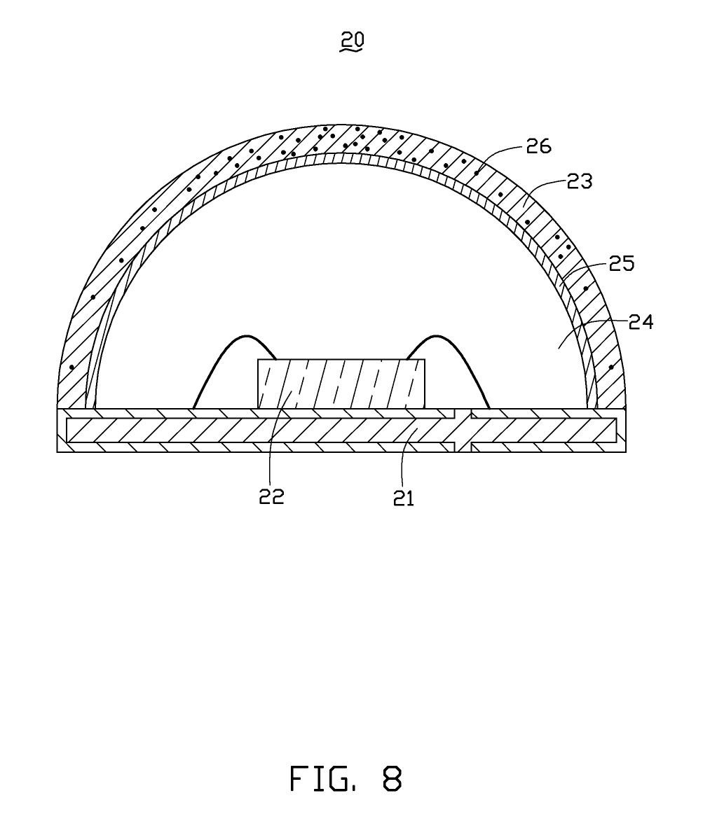

Referring to FIG. 8, an LED package 20 in accordance with a fifth embodiment includes a substrate 21, an LED die 22 arranged on the substrate 21, and an encapsulating layer 23 covering the LED die 22. There is a space 24 defined between the substrate 21 and the encapsulating layer 23. The difference from the first embodiment is that a layer of luminescent material 25 is arranged on the inner surface of the encapsulating layer 23, and there is no luminescent material in the encapsulating layer 23. The layer of luminescent material 25 is spaced from the LED die 22 with a certain distance to prevent the layer of luminescent material 25 from high temperature. A plurality of light scattering particles 26 is arranged inside the encapsulating layer 23. The density of the plurality of light scattering particles 26 is proportional to the light intensity illuminated on the encapsulating layer 23 from the LED die 22. In this embodiment, the intensity of light illuminated on the encapsulating layer 23 from the Led die 22, and, correspondingly, densities of the light scattering particles 26 are higher at the center and lower at the bottom. The light scattering particles 26 can be TiO₂, plastic, polymethylmethacrylate (PMMA), fused silica, Al₂O₃, MgO, or other transparent oxide. The shape of the light scattering particles 26 is not limited and can be spherical, longitudinal, or other shape. In this embodiment, the light scattering particles 26 are spherical.

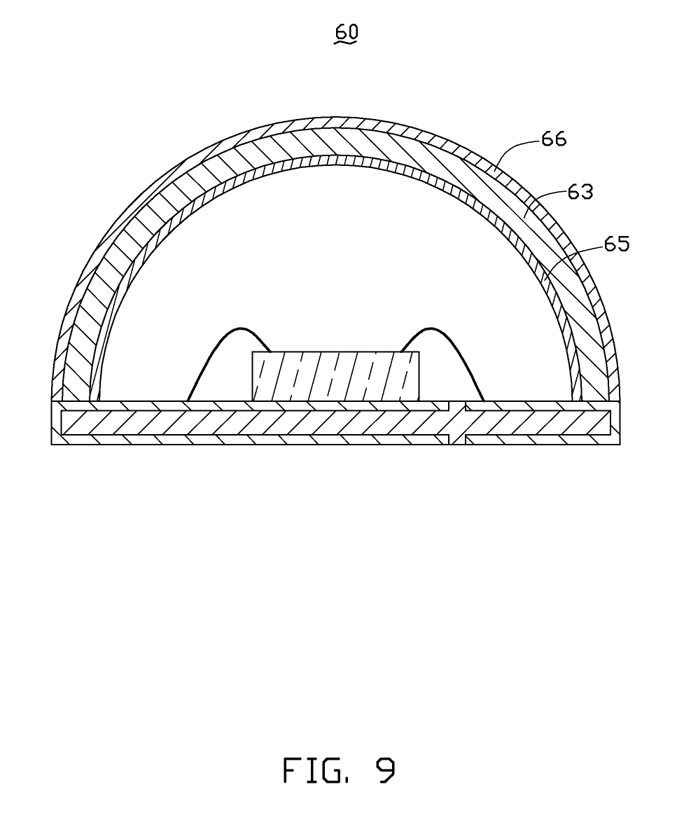

FIG. 9 shows an LED package 60 in accordance with a sixth embodiment including a layer of luminescent material 65 arranged on the inner surface of the encapsulating layer 63. The difference from the fifth embodiment is that an atomization layer 66 is arranged on the outer surface of the encapsulating layer 63 without any light scattering particles inside the encapsulating layer 63.

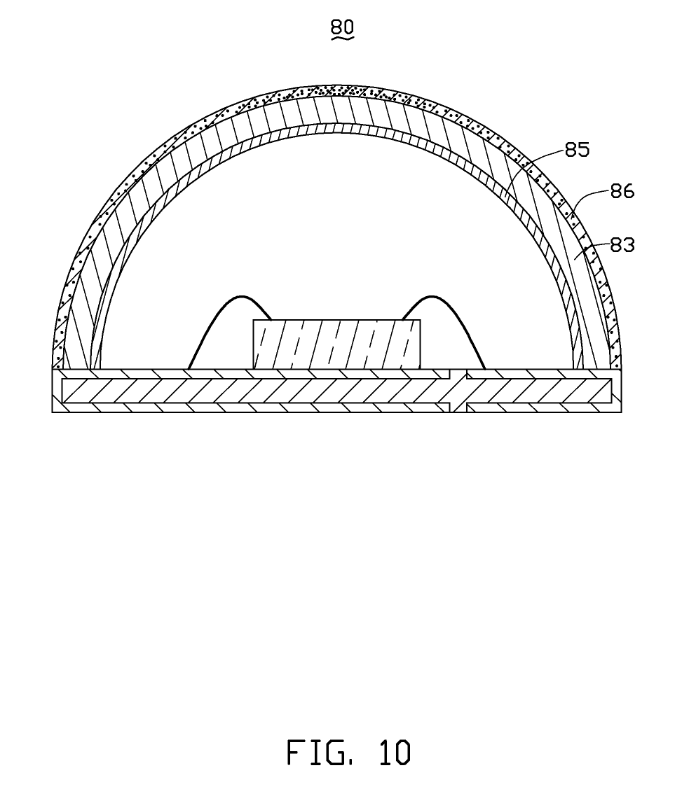

FIG. 10 shows an LED package 80 in accordance with a seventh embodiment including a layer of luminescent material 85 arranged on the inner surface of an encapsulating layer 83. The difference from the sixth embodiment is that a sandblasted layer 86 is arranged on the outer surface of the encapsulating layer 83 to replace the atomization layer 66 of the sixth embodiment.

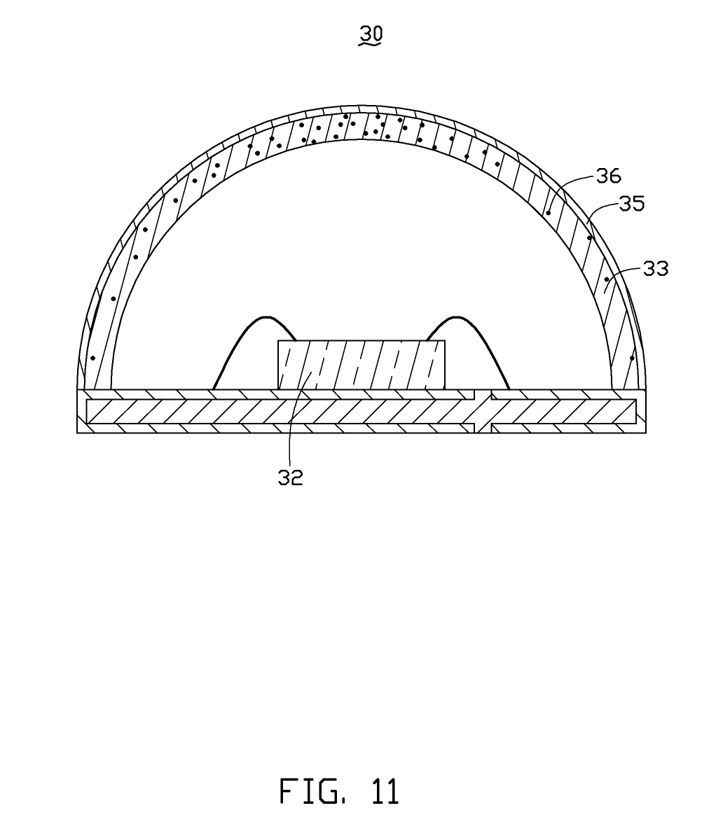

FIG. 11 shows an LED package 30 in accordance with an eighth embodiment including an LED die 32, an encapsulating layer 33, and a plurality of light scattering particles 36 inside the encapsulating layer 33. This embodiment is similar to the fifth embodiment of FIG. 8 except that a layer of luminescent material 35 is arranged on the outer surface of the encapsulating layer 33. The density of the luminescent material in the layer of luminescent material 35 is proportional to the light intensity illuminated on the encapsulating layer 33 from the LED die 32. The densities of the light scattering particles 36 are proportional to the light intensity illuminated on the encapsulating layer 33 from the LED die 32. The layer of luminescent material 35 can be arranged on the inner surface, the outer surface, or both the two surfaces of the encapsulating layer 33 to increase the uniformity of light emitted out from the LED die 32. The outer surface of the layer of luminescent material 35 can include an atomization layer or a sandblasted layer or both.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED package comprising:
a substrate;
an LED die arranged on the substrate; and
an encapsulating layer covering the LED die, wherein the encapsulating layer further comprises a light dispersing element with a light scattering intensity in proportional to a light intensity of light generated by the LED die and illuminated on the encapsulating layer.

2. The LED package of claim 1, wherein the light dispersing element is an atomization layer or a sandblasting layer on an surface of the encapsulating layer.

3. The LED package of claim 2, wherein a density of atomization of the atomization layer or micro-recesses of the sandblasting layer decreases from a center to a periphery of the encapsulating layer.

4. The LED package of claim 1, wherein the light dispersing element includes light scattering particles in the encapsulating layer.

5. The LED package of claim 4, wherein a density of the light scattering particles decreases from a center to a periphery of the encapsulating layer.

6. The LED package of claim 1, wherein the encapsulating layer includes luminescent material with a space between the luminescent material and the LED die.

7. The LED package of claim 6, wherein the luminescent material is at an outer surface, an inner surface, or an inside of the encapsulating layer.

8. The LED package of claim 6, wherein the luminescent material is garnet compound, silicate, sulfide, phosphate, nitride, oxynitride, or SiAlON.

9. The LED package of claim 1, wherein a density of the luminescent material is proportional to the light intensity of light generated by the LED die and illuminated on the encapsulating layer.

10. The LED package of claim 9, wherein the density of the luminescent material decrease from a center to a periphery of the encapsulating layer.

11. An LED package comprising:
a substrate;
an LED die arranged on the substrate; and
an encapsulating layer with luminescent material covering the LED die, wherein the encapsulating layer further comprises a light dispersing element with a light scattering intensity and luminescent material density in proportional to a light intensity of light generated by the LED die and illuminated on the encapsulating layer.

12. The LED package of claim 11, wherein the encapsulating layer has a configuration of a hollow hemisphere.

13. The LED package of claim 11, wherein the encapsulating layer has a configuration of a solid hemisphere.
